(19) United States
(12) Patent Application Publication
(10) Pub. No.: US 2025/0140518 A1
(43) Pub. Date: May 1, 2025

(54) MACHINING METHOD AND CHARGED PARTICLE BEAM DEVICE

(71) Applicant: HITACHI HIGH-TECH SCIENCE CORPORATION, Tokyo (JP)

(72) Inventors: Toshiyuki NAGAMINE, Tokyo (JP); Atsushi UEMOTO, Tokyo (JP); Tatsuya ASAHATA, Tokyo (JP); Xin MAN, Tokyo (JP)

(21) Appl. No.: 18/692,790

(22) PCT Filed: Sep. 28, 2021
(86) PCT No.: PCT/JP2021/035604

§ 371 Date: Mar. 15, 2024

(51) Int. Cl. H01J 37/304; H01J 37/26; H01J 37/30; H01J 37/305

(52) U.S. Cl. CPC H01J 37/304; H01J 37/26; H01J 37/3005; H01J 37/3053; H01J 2237/221; H01J 2237/30472; H01J 2237/31749

(57) ABSTRACT

This machining method includes: a machining step of irradiating a sample constituted from a stack of multiple layers with a focused ion beam so as to machine a cross-section of the sample by a predetermined amount; an image generation step of generating an observation image of the cross-section of the sample by irradiating the sample with an electron beam after the machining step is ended; and a specific-layer determination step of determining whether a specific layer of the multiple layers is exposed based on the observation image.

### CROSS REFERENCE

The present application for patent is a 371 national phase filing of International Patent Application No. PCT/JP2021/035604, by NAGAMINE et al., entitled “MACHINING METHOD AND CHARGED PARTICLE BEAM DEVICE,” filed Sep. 28, 2021, assigned to the assignee hereof, and expressly incorporated by reference herein.

### TECHNICAL FIELD

The present invention relates to a machining method and a charged particle beam device.

### BACKGROUND ART

To observe a sample with a transmission electron microscope (TEM) or the like, a charged particle beam device for etching the sample into a shape suitable for observation is known (for example, Patent Document 1)

### DOCUMENT OF RELATED ART

### Patent Document

Patent Document 1: Japanese Patent Application Publication No. 2013-120714

### DISCLOSURE

### Technical Problem

When a specific layer (hereinafter referred to as “specific layer”) in a layered sample is observed, it is required to expose the specific layer by etching or the like. To do this, it is required to accurately detect a specific layer of a sample.

The present invention has been made in view of these circumstances, and the objective of the present invention is to accurately detect a specific layer of a sample.

### Technical Solution

(1) An aspect of the present invention is a machining method including: a machining step of processing a cross-section of a sample in which a plurality of layers is laminated by a predetermined amount by irradiating the sample with a focused ion beam; an image generation step of generating an observation image of the cross-section of the sample by irradiating the sample with an electron beam after completion of the machining step; and specific layer determination step of determining whether a specific layer among the plurality of layers is exposed based on the observation image.

(2) The machining method of (1) above, in which the machining step, with the image generation step, and the specific layer determination step being a set, the set is repeatedly executed until exposure of the specific layer is detected in the specific layer determination step.

(3) The machining method of (1) above, further including a pre-processing step of acquiring the contrast of the observation image while executing processing of the cross-section by irradiating the sample with the focused ion beam and, in case the contrast changes, stopping the processing of the cross-section and focusing the electron beam, in which the pre-processing step may be executed before the machining step that is executed initially.

(4) The machining method of (1) or (2) above, further including a pre-processing step of focusing the electron beam, the pre-processing step being executed before the machining step that is executed initially. The pre-processing step may include: an observation image acquisition step of acquiring the observation image while processing the cross-section by irradiating the sample with the focused ion beam; an exposure determination step of determining whether a layer having a pattern is exposed or not by inputting the observation image acquired in the observation image acquisition step to a learning model that has been previously trained with observation images of a layers having no pattern and observation images of the layers having the pattern among the plurality of layers as training data; and a focusing step of stopping the processing of the cross-section and focusing the electron beam, in case it is determined that the layer having the pattern is exposed in the exposure determination step.

(5) The machining method of (1) or (2) above, further including a pre-processing step of focusing the electron beam based on the observation image of a pattern of a deposit attached to a surface of the sample, in which the pre-processing step is executed before the machining step that is executed initially.

(6) The machining method of any one of (1) through (5) above, in which the specific layer determination step determines whether the specific layer is exposed based on a result of determination output from a learning model that determines whether an image that is input is an image of the specific layer by inputting the observation image generated in the image generation step to the learning model, and confidence level presenting certainty of the result of determination.

(7) The machining method of any one of (1) through (5) above, in which the specific layer determination step identifies a machining layer, which is a layer being processed in the machining step, based on a result of determination output from a learning model that determines an image of which layer among the plurality of layers an input image is, by inputting the observation image generated in the image generation step to the learning model, and determines that the machining layer is mis-identified in case the machining layer identified is different from a preset layer.

(8) The machining method of any one of (1) through (5) above, in which the specific layer determination step identifies a machining layer, which is a layer being processed in the machining step, based on a result of determination output from a learning model that determines an image of which layer among the plurality of layers an input image is, by inputting the observation image obtained in the image generation step to the learning model, and detects layer switching to the specific layer in case the machining layer is a layer that is immediately before the specific layer and confidence level of the result of determination is decreased.

(9) The machining method of any one of (1) through (5) above, in which the specific layer is a k-th layer from a surface of the sample in a direction in which layers are stacked, the specific layer determination step identifies a machining layer, which is a layer being processed in the machining step, based on a result of determination output from a learning model that determines an image of which layer among the plurality of layers an input image is, by inputting the observation image generated in the image generation step to the learning model, and the machining step reduces the predetermined amount in case the machining layer determined in the specified layer determination step is a (k−n)-th layer (n is an integer).

(10) One aspect of the invention a machining method including: a machining step of processing a cross-section of a sample in which a plurality of layers is laminated by a predetermined amount, by irradiating the sample with a focused ion beam; an image generation step of generating an observation image of the cross-section of the sample by irradiating the sample with an electron beam; and a specific layer determination step of determining whether a specific layer among the plurality of layers is exposed, based on the observation image, in which the specific layer is the k-th layer from the surface of the sample in a direction in which layers are stacked, the specific layer determination step identifies a machining layer, which is a layer being processed in the machining step, based on a result of determination output from a learning model that determines an image of which layer among the plurality of layers an input image is, by inputting the observation image generated in the image generation step to the learning model, and the machining step and the image generation step are concurrently executed when the processing of the sample starts, and, in case the machining layer is a (k−n)-th layer (n is an integer), the machining step and the image generation step are executed at different points in time.

(11) An aspect of the present invention is a charged particle beam device including: a focused ion beam column configured to process a cross-section of a sample in which a plurality of layers is laminated by a predetermined amount, by irradiating the sample with a focused ion beam; an ion beam column configured to irradiate the sample with an electron beam after the predetermined amount of processing with the focused ion beam column is finished; an observation image generation unit configured to generate an observation image of a cross-section of the sample based on electrons generated from the sample; and a determination unit configured to determine whether a specific layer among the plurality of layers is exposed based on the observation image.

### Advantageous Effects

As described above, according to the present invention, a specific layer of a sample can be accurately processed.

### DESCRIPTION OF RELATED ART

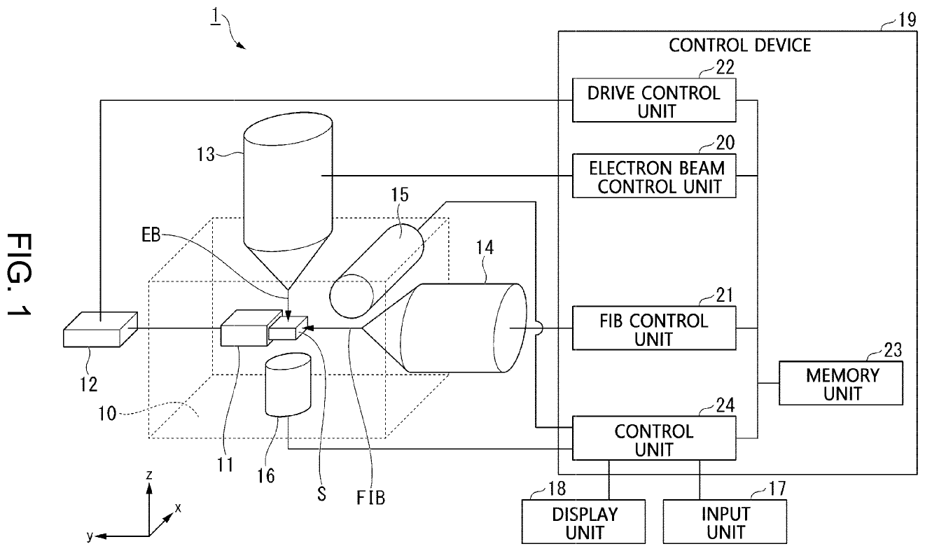

FIG. 1 is a diagram illustrating one example of the configuration of a charged particle beam device according to a first embodiment.

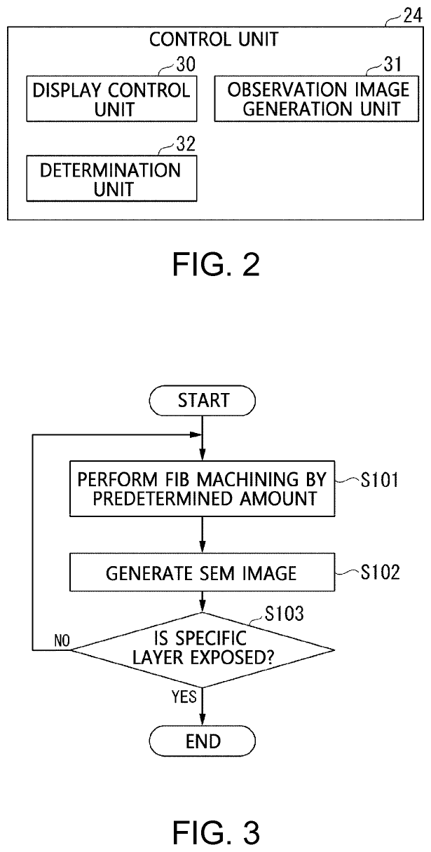

FIG. 2 is a diagram illustrating one example of the configuration of a control unit according to the first embodiment.

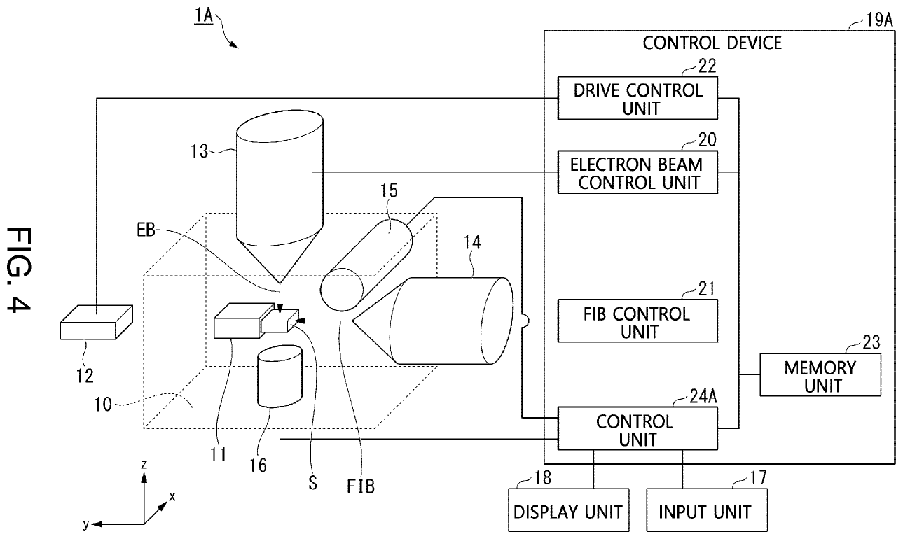

FIG. 3 is a flow diagram illustrating an exposure machining method according to the first embodiment.

FIG. 4 is a diagram illustrating one example of the configuration of a charged particle beam device according to a second embodiment.

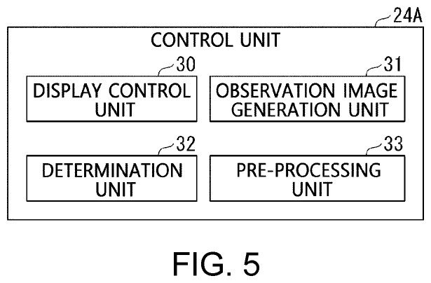

FIG. 5 is a diagram illustrating one example of the configuration of a control unit according to the second embodiment.

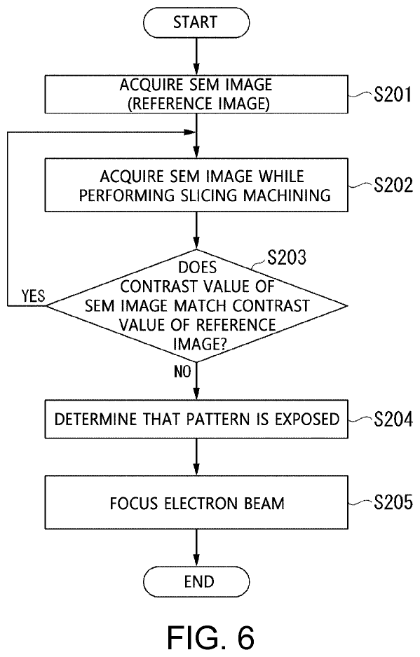

FIG. 6 is a flow diagram illustrating first pre-processing according to the second embodiment.

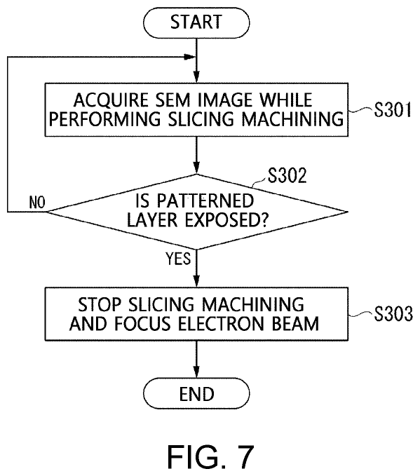

FIG. 7 is a flow diagram illustrating second pre-processing according to the second embodiment.

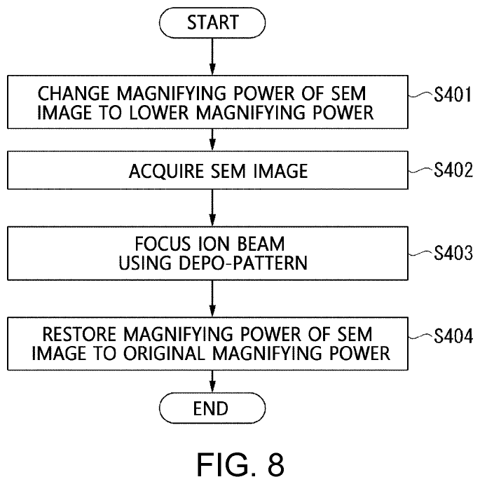

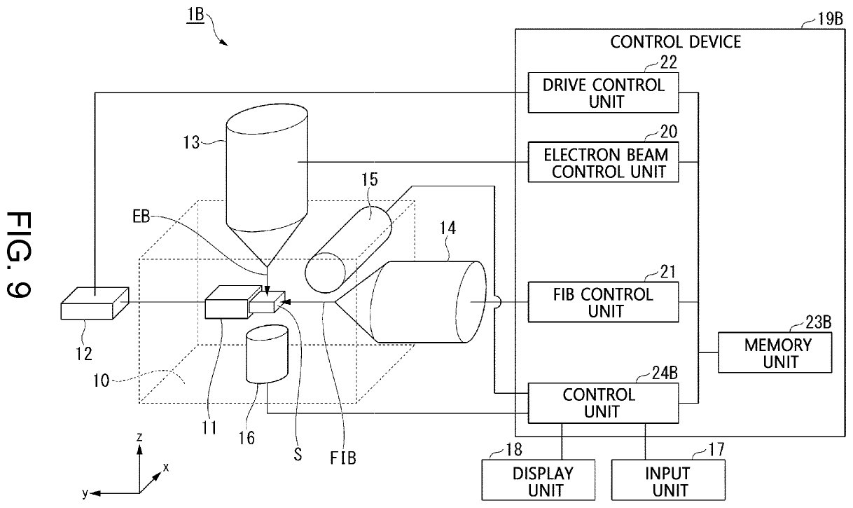

FIG. 8 is a flow diagram illustrating third pre-processing according to the second embodiment.

FIG. 9 is a diagram illustrating one example of the configuration of a charged particle beam device according to a third embodiment.

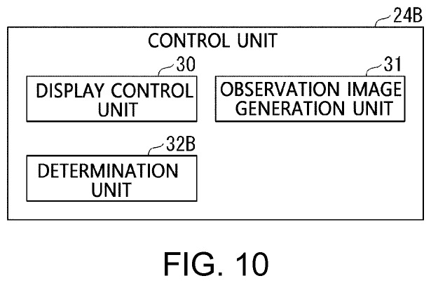

FIG. 10 is a diagram illustrating one example of the configuration of a control unit according to the third embodiment.

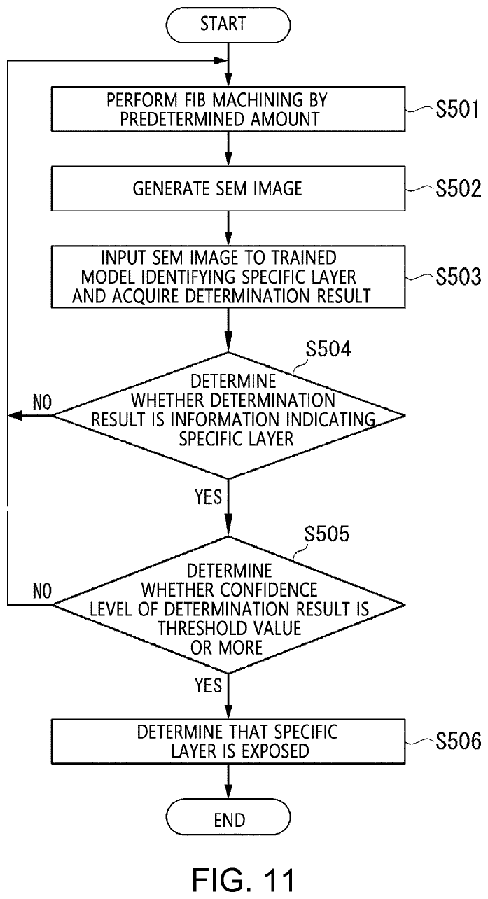

FIG. 11 is a flow diagram illustrating an exposure machining method according to the third embodiment.

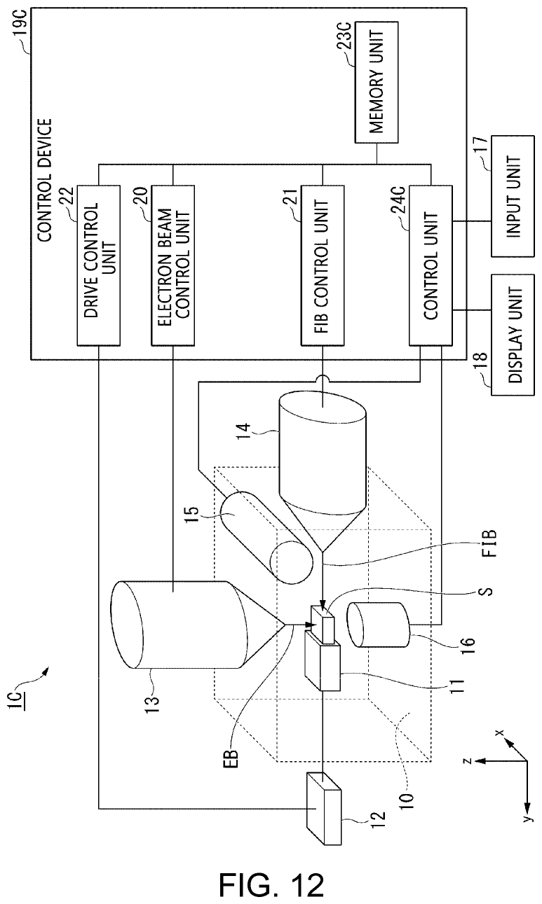

FIG. 12 is a diagram illustrating one example of the configuration of a charged particle beam device according to a fourth embodiment.

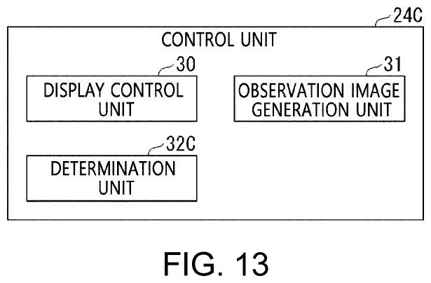

FIG. 13 is a diagram illustrating one example of the configuration of a control unit according to the fourth embodiment.

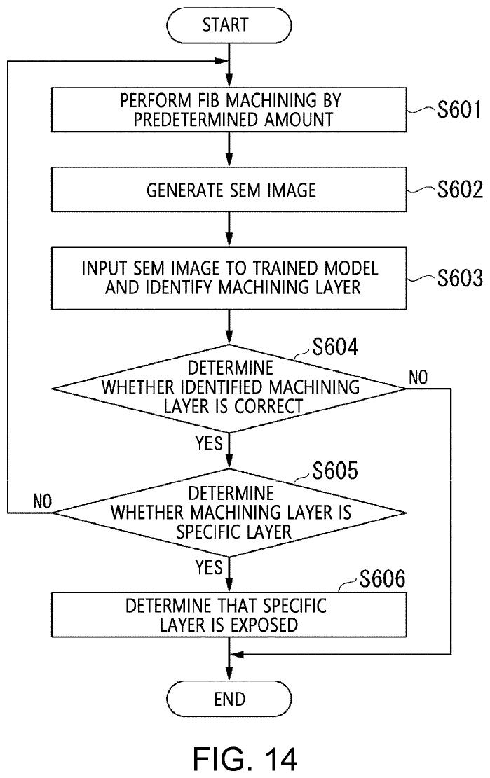

FIG. 14 is a flow diagram illustrating an exposure machining method according to the fourth embodiment.

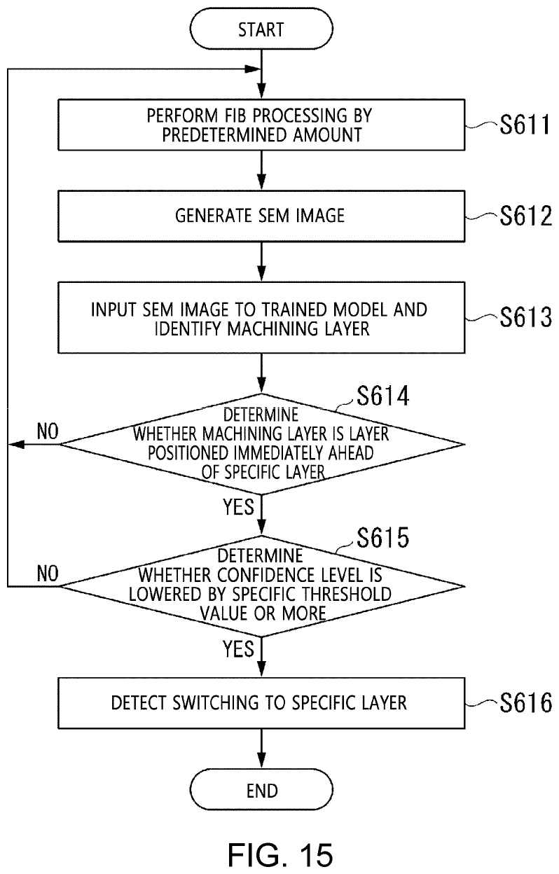

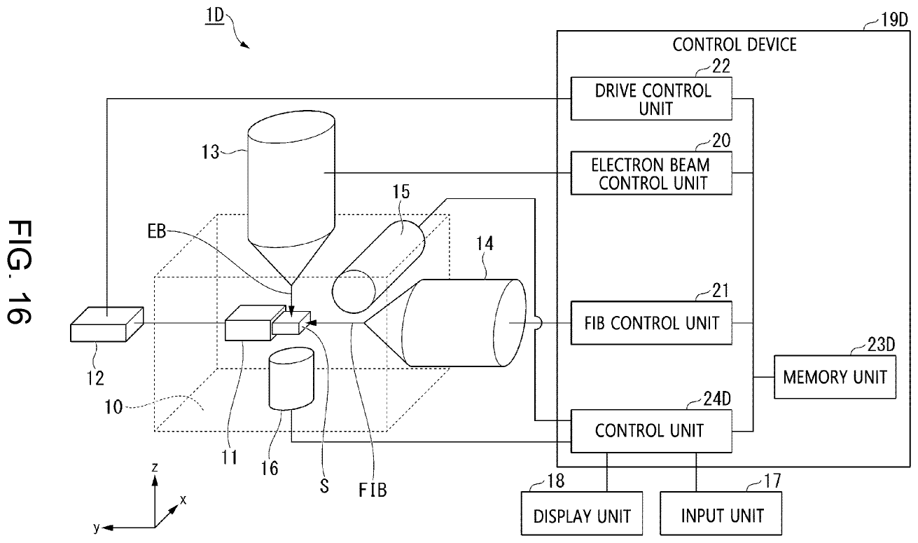

FIG. 15 is a flow diagram illustrating a modification to the exposure machining method according to the fourth embodiment.

FIG. 16 is a diagram illustrating one example of the configuration of a charged particle beam device according to a fifth embodiment.

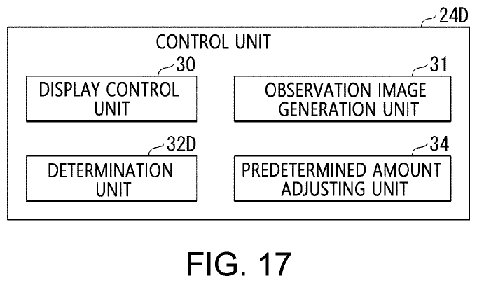

FIG. 17 is a diagram illustrating one example of the configuration of a control unit according to the fifth embodiment.

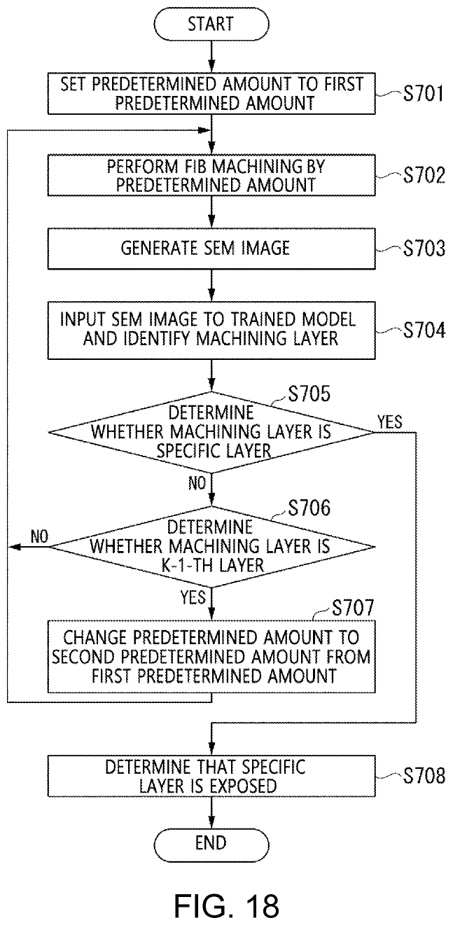

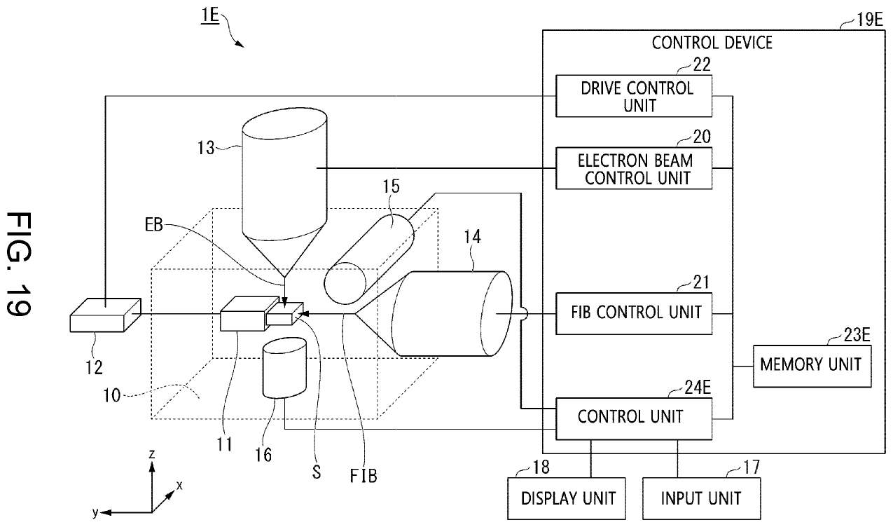

FIG. 18 is a flow diagram illustrating an exposure machining method according to the fifth embodiment.

FIG. 19 is a diagram illustrating one example of the configuration of a charged particle beam device according to a sixth embodiment.

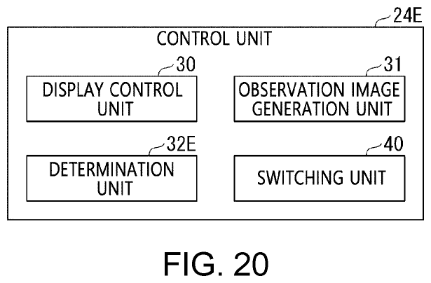

FIG. 20 is a diagram illustrating one example of the configuration of a control unit according to the sixth embodiment.

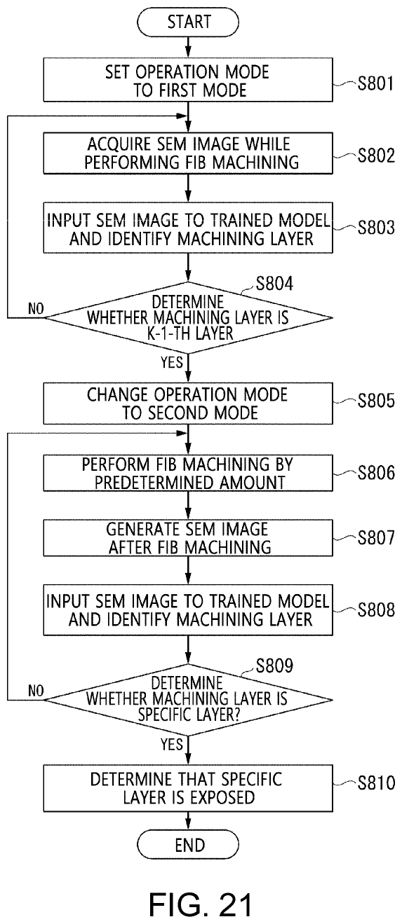

FIG. 21 is a flow diagram illustrating an exposure machining method according to the sixth embodiment.

### BEST MODE

Hereinafter, a charged particle beam device according to one embodiment will be described with reference to the accompanying drawings. A charged particle beam device irradiates a sample S in which a plurality of layers is laminated with a focused ion beam, thereby processing a cross-section of the sample. For example, when a certain layer (specific layer) of a sample S with multiple layers laminated is to be observed by a transmission electron microscope (TEM) or the like, it is necessary to process a cross-section of the sample to expose the specific layer. In this case, a charged particle beam device performs processing to expose the specific layer, and determines whether the specific layer is exposed while checking SEM images of the cross-section of the sample. One of the features of the present embodiment is to acquire high-resolution SEM images by executing the processing of the cross-section of the sample and the generation of SEM images at different points in time and to enable accurate detection of a specific layer.

The state that the specific layer is exposed may mean that the specific layer is fully exposed or that the specific layer is partially exposed. In other words, detection of a specific layer may mean detecting exposure of a portion of the specific layer, or detecting exposure of the entire specific layer. Detecting exposure of a portion of a specific layer may be detecting a switch from one layer to the specific layer.

Here, the sample S is a sample in which a plurality of layers including a specific layer is laminated in a predetermined lamination direction. The specific layer is a layer made of a material to be observed (for example, a semiconductor). In addition, aside from the multiple specific layers, the sample S may have one or more non-observation target layers laminated in the lamination direction. The non-observation target layer is a layer made of a material not to be observed (for example, a metal conductor used as a power line or a signal transmission line). The sample S is, for example, a 3D-NAND flash memory. In addition, the lamination direction may be an arbitrary direction. Hereinafter, for example, the lamination direction of the sample S disposed in a sample chamber 10 may be an up-down direction or a left-right direction.

### First Embodiment

Hereinafter, the configuration of a charged particle beam device 1 according to a first embodiment will be described in detail.

FIG. 1 is a diagram illustrating one example of the configuration of a charged particle beam device 1 according to the first embodiment. As illustrated in FIG. 1, the charged particle beam device 1 includes a sample chamber 10, sample stand 11, a drive mechanism 12, an electron beam column 13, a focused ion beam column 14, a secondary charged particle detector 15, a transmission electron detector 16, an input unit 17, a display unit 18, and a control device 19.

The sample chamber 10 is defined by an airtight, pressure-tight casing capable of maintaining the desired predetermined reduced pressure. The interior of the sample chamber 10 can be evacuated with an air exhauster (not shown) until the interior of the sample chamber 11 has the desired reduced pressure.

The sample stand 11 is a member to support the sample S and is disposed inside the sample chamber 10. The sample stand 11 is driven by the driving mechanism 12.

The driving mechanism 12 three-dimensionally translates and rotates the sample table 11. The driving mechanism 12 moves the sample stand 11 backwards and forwards along each axial direction of X-axis, Y-axis, and Z-axis directions in three-dimensional space, for example. The Z axis is the up-down direction and is orthogonal to a plane (XY plane) formed by the X axis and the Y axis. In addition, the driving mechanism 12 includes, for example, a tilt mechanism that rotates the sample stand around the X or Y axis and a rotation mechanism that rotates the sample stand around the Z axis. Hereinafter, the angle by which the sample stand 11 is rotated by the tilt mechanism is referred to as a tilt angle.

The electron beam column 13 applies an electron beam (EB), which is an example of the charged particle beam, to the sample S disposed inside the sample chamber 10. For example, the direction in which the electron beam is applied is parallel to the Z-axis direction. In addition, for convenience of explanation, the direction parallel to the Z-axis direction is hereinafter referred to as the up-down direction, and the vertical direction of the up-down direction is referred to as the downward direction and the direction opposite to the vertical direction is referred to as the upward direction.

The focused ion beam column 14 applies a focused ion (FIB) to the sample S disposed inside the sample chamber 10. The cross-section of the sample S is thereby processed. In the following description, processing the sample S with a focused ion beam is sometimes referred to as “FIB machining”. The irradiation direction of the focused ion beam is, for example, parallel to the XY plane. In the example shown in FIG. 1, the irradiation direction of the electron beam column 13 and the irradiation direction of the focused ion beam column 14 are orthogonal to each other on the sample S. However, the invention is not limited thereto, and the focused ion beam column 14 may be arranged in the up-down direction or a tilt direction that is inclined with respect to the up-down direction. Here, in the present embodiment, for example, the FIB machining is performed parallel to the layers of the sample.

The secondary charged particle detector 15 detects secondary electrons generated from the sample S irradiated with the ion beam or focused ion beam. The secondary charged particle detector 21 transmits the detection result of the secondary electrons to the control device 19.

The transmission electron detector 16 detects transmission electrons passing through the sample S and an electron beam not incident on the sample S when the sample S is irradiated with an electron beam. The transmission electron detector 21 transmits the detection result to the control device 19.

The input unit 17 is, for example, a mouse and keyboard that output signals corresponding to input operations made by the operator.

The display unit 18 includes a display device such as a liquid crystal display (LCD) device. The display unit 18 displays various types of information of the charged particle beam device 1, image data generated based on signals output from the secondary charged particle detector 15, and screens for allowing operations such as zooming in, zooming out, moving, and rotating the image data.

The control device 19 controls the overall operation of the charged particle beam device 1. The control device 19 includes an electron beam control unit 20, a focused ion beam control unit (FIB control unit) 21, a drive control unit 22, a memory unit 23, and a control unit 24.

The electron beam control unit 20 outputs an irradiation signal to the electron beam column 13 based on the signals output from the control unit 24, thereby causing the electron beam column 13 to emit an electron beam.

The focused ion beam control unit 21 outputs an irradiation signal to the focused ion beam column 14 based on the signals output from the control unit 24, thereby causing the focused ion beam column 14 to emit a focused ion beam. The focused ion beam control unit 21 can adjust the irradiation direction of the focused ion beam emitted from the focused ion beam column 14 based on signals output from the control unit 24.

The drive control unit 22 controls the drive of the drive mechanism 12 based on the signals output from the control unit 24, and translates the sample stand 11 or changes the tilt angle by outputting a drive signal to the drive mechanism 12 to drive the sample stand 11.

The memory unit 23 is equipped with a hard disk drive, flash memory, etc., and stores various types of information. The memory unit 23 stores information on the processing conditions for FIB machining. The charged particle beam device 1 performs scanning with a focused ion beam within a scanning area according to the processing conditions stored in the memory unit 23. This allows the charged-particle beam system 1 to perform etching within the scanning area and formation of an observation image of the scanning area using a focused ion beam. The processing conditions include scanning area information indicating the scanning area, information indicating the acceleration voltage of the electron beam, information indicating the beam current, information indicating the magnifying power, information indicating the contrast, information indicating the brightness, information indicating the thickness of a layer to be etched, information indicating the etching depth, information indicating the distance from the focused-ion beam column 14 to the surface of the sample S, etc.

FIG. 2 is a diagram illustrating one example of the configuration of the control unit 24 according to the first embodiment. The control unit 24 includes a display control unit 30, an observation image generation unit 31, and a determination unit 32.

The display control unit 30 causes the display unit 18 to display the transmission images and SEM images described above.

The observation image generation unit 31 forms the transmission images based on an electron beam scanning signal of the electron beam control unit 20 and a signal of transmission electrons detected by the transmission electron detector 16. The observation image generation unit 31 forms data of the SEM image based on an electron beam scanning signal of the electron beam control unit 20 and the signal of secondary electrons detected by the secondary charged particle detector 15. The observation image in the present embodiment is an SEM image. However, the observation image can be a transmission image.

The determination unit 32 determines whether a specific layer among the plurality of layers of the sample S is exposed based on the observation image generated by the observation image generation unit. For example, the determination unit 32 applies an existing image processing method to the observation image generated by the observation image generation unit 31 and identifies a pattern of the cross-section taken in the observation image. Then, when the pattern identified is the pattern of a specific layer registered in advance in the memory unit 23, etc., the determination unit 32 determines that the specific layer is exposed. However, the invention is not limited to thereto. The determination unit 32 may determine whether the specific layer is exposed based on the observation image by using known techniques.

Hereinafter, a machining method in which the charged particle beam device 1 performs an operation of exposing a specific layer will be described. This method will be referred to as “exposure machining method”. FIG. 3 is a flow diagram illustrating an exposure machining method according to a first embodiment.

### [Exposure Machining Method]

The charged particle beam device 1 reads processing conditions stored in the memory unit 23 and performs FIB machining according to the processing conditions. First, the charged particle beam device 1 forms a new cross-section by slicing the cross-section of the sample S by a predetermined amount by irradiating the sample S with a focused ion beam (step S101: machining step). When the new cross-section is formed, the charged particle beam device 1 stops the FIB machining, irradiates the new cross-section formed with an electron beam, and generates an observation image (SEM image) of the cross-section (Step S102: image generation step). In other words, the observation image generation unit 31 executes the image generation step after the machining step.

The charged particle beam device 1 determines whether the specific layer is exposed based on the SEM image generated in the image generation step (step S103: specific layer determination step). For example, the determination unit 32 compares the SEM image obtained in the image generation step with a cross-section image of the specified layer stored in advance in the memory unit 23 (hereinafter referred to as “target cross-section image”) and determines whether the SEM image and the target cross-sectional image match each other. When the SEM image obtained in the image generation step does not match the target cross-section image stored in advance in the memory unit 23, the determination unit 32 determines that the specific layer is not exposed, and the process flow returns to step S101 so that the slicing is executed again. On the other hand, when the SEM image obtained in the image generation step matches the target cross-section image stored in advance in the memory unit 23, the determination unit 32 determines that the specific layer is exposed. When the determination unit 32 determines that the specific layer is exposed, the charged particle beam device 1 finishes the series of processes shown in FIG. 3. That is, with the machining step, the image generation step, and the specific layer determination step being a set, the charged particle beam device 1 repeatedly executes the set of steps until exposure of the specific layer is detected in the specific layer determination step.

After the exposure of the specific layer is detected, the charged particle beam device 1 may stop the FIB machining or resume the processing of the specific layer after switching to the processing conditions for the specific layer.

In this way, the charged particle beam device 1 of the present embodiment does not execute the machining step and the image generation step at the same time but at different points in time. In other words, the observation image generation unit 1 executes the image generation step after the machining step. This allows the charged particle beam device 1 to generate SEM images without being affected by the FBI machining, whereby high-resolution SEM images can be obtained. As a result, the charged particle beam device 1 can accurately detect the specific layer. In addition, in the present embodiment, there is no period during which the machining step and the image generation step are concurrently executed. However, there may be a period during which the machining step and the image generation step may be only partially concurrently.

### Second Embodiment

Hereinafter, a charged particle beam device 1A according to a second embodiment will be described in detail. In the description given below, parts that have the same functions as those in the first embodiment will be denoted by the same names and reference numerals, and a redundant description thereabout will be omitted. Compared to the charged particle beam device 1 of the first embodiment, the charged particle beam device 1A of the second embodiment differs in that pre-processing is performed before the FIB machining that is executed initially. However, other functions and configurations are the same.

FIG. 4 is a diagram illustrating one example of the schematic configuration of the charged particle beam device 1A according to the second embodiment. As illustrated in FIG. 4, the charged particle beam device 1A includes a sample chamber 10, sample stand 11, a drive mechanism 12, an electron beam column 13, a focused ion beam column 14, a secondary charged particle detector 15, a transmission electron detector 16, an input unit 17, a display unit 18, and a control device 19A.

The control device 19A controls the overall operation of the charged particle beam device 1A. The control device 19A includes an electron beam control unit 20, a focused ion beam control unit 21, a drive control unit 22, a memory unit 23, and a control unit 24A. In addition, as illustrated in FIG. 5, the control unit 24A includes a display control unit 30, an observation image generation unit 31, a determination unit 32, and a pre-processing unit 33.

The pre-processing unit 33 executes a pre-processing step, which is the process of focusing the electron beam, before the FIB machining that is executed initially. This pre-processing is executed when no pattern appears on the processed surface of the sample S, for example, when the cross-section of the sample S has not been processed. In other words, the pre-processing is executed when the layer with no pattern in the sample S (hereinafter referred to as the “un-patterned layer”) is exposed. The un-patterned layer is not a specific layer and is not an observation target. When no pattern appears on the processed surface of the sample S, it is difficult to focus the electron beam on that surface. Therefore, the pre-processing unit 33 can focus the electron beam by executing the pre-processing when no pattern appears on the processed surface of the sample S.

There are three main pre-processing methods: first pre-processing, second pre-processing, and third pre-processing. The pre-processing unit 33 may execute the pre-processing using any of the three pre-processing methods.

### [First Pre-Processing]

First, the first pre-processing will be described. FIG. 6 is a flow diagram illustrating the first pre-processing. The charged particle beam device 1A first irradiates the processed surface with an electron beam to obtain an SEM image of the processed surface (step S201). The charged particle beam device 1A stores the SEM image acquired in step S201 as a reference image in the memory unit 23. Next, the charged particle beam device 1 irradiates a sample S with a focused ion beam, thereby acquiring SEM images while performing cross-section slicing machining (step S202). Then, each time the charged particle beam device 1A acquires an SEM image in step S202, it compares the contrast value of the SEM image with the contrast value of the reference image (step S203). The charged particle beam device 1A determines that a pattern is exposed when the result of comparing the contrast value of the SEM image with the contrast value of the reference image reveals that there is a change in the contrast value of the SEM image obtained in step S202 compared to the contrast value of the reference image (step S204). On the other hand, when there is no change in the contrast value of the SEM image obtained in step S202 compared to the contrast value of the reference image, the charged particle beam device 1A determines that the pattern is not exposed and executes step S202 again.

Once the pattern is exposed, the electron beam can be focused. Therefore, when it is determined that the pattern is exposed, the charged particle beam device 1A focuses the electron beam on the cross-section of the sample (step S205).

### [Second Pre-Processing]

The second pre-processing will be described. FIG. 7 is a flow diagram illustrating the second pre-processing. First, the charged particle beam device 1A irradiates the sample S with a focused ion beam, thereby acquiring SEM images while performing cross-section slicing machining (step S301: observation image acquisition step). Next, the charged particle beam device 1A inputs the SEM image acquired in the observation image acquisition step to a learning model (first trained model) trained with training data that are images of the respective layers of the sample S (for example, SEM image) and determines whether a layer with a pattern (hereinafter referred to as “patterned layer) is exposed (step S302: exposure determination step). When the first trained model receives an SEM image as an input image, the first trained model outputs a result of determination of whether the input image (SEM image) is an image of a patterned layer or an image of an un-patterned layer. For example, the training data may include an image of an un-patterned layer (i.e., processed surface of the sample having not undergone FIB machining) and an image of the next layer (patterned layer) to the un-patterned layer. The charged particle beam device 1A, for example, has the first trained model stored in advance in the memory 23. The first trained model may be created in the charged particle beam device 1A or in a device separated from the charged particle beam device 1A.

When the first trained model determines that the input image is an image of a patterned layer, the charged particle beam device 1A determines that the patterned layer is exposed. When the patterned layer is determined to be exposed in the exposure determination step, the charged particle beam device 1A stops slicing machining of the cross-section and executes a focusing step of focusing the electron beam on the cross-section (step S303: focusing step). On the other hand, when the first trained model determines that the input image is an image of an un-patterned layer, the charged particle beam device 1A determines that the patterned layer is not exposed. When it is determined that the patterned layer is not exposed in the determination step, the charged particle beam device 1A continues the process of step S301 and executes steps S302 and S303 again.

### [Third Pre-Processing]

The third pre-processing will be described. FIG. 8 is a flow diagram illustrating the third pre-processing. First, the charged particle beam device 1A changes the magnifying power of the SEM image to a lower magnifying power to the extent that a pattern of deposits attached to the surface of the sample (hereinafter referred to as a “depo-pattern”) can be obtained in the form of an SEM image (step S401). Then, the charged particle beam device 1A acquires an SEM image of the surface of the sample S after changing the magnifying power of the SEM image to a lower magnifying power (step S402). The charged particle beam device 1A focuses the electron beam using the depo-pattern taken in the SEM image acquired in step S402 (step S403). After focusing the electron beam force, the charged particle beam device 1A changes the magnifying power of the SEM image from the low magnifying power to the original magnifying power (step S404).

The charged particle beam device 1A executes exposure machining after any of the first, second, and third pre-processing methods is executed. The exposure machining of the second embodiment is the same as that of the first embodiment, and a description thereof will be omitted.

The charged particle beam device 1A of the second embodiment exhibits the same effects as the charged particle beam device 1 of the first embodiment. In addition, since the charged particle beam device 1A of the second embodiment executes the pre-processing before the exposure machining, the exposure machining can be performed even though the processed surface is an un-patterned layer.

### Third Embodiment

Hereinafter, a charged particle beam device 1B according to a third embodiment will be described in detail. In the description given below, parts that have the same functions as those in the first embodiment will be denoted by the same names and reference numerals, and a redundant description thereabout will be omitted. Compared to the charged particle beam device 1 of the first embodiment, the charged particle beam device 1B of the third embodiment differs in the process of determining whether a specific layer is exposed, but other functions and configurations are the same.

FIG. 9 is a diagram illustrating one example of the schematic configuration of the charged particle beam device 1B according to the third embodiment. As illustrated in FIG. 9, the charged particle beam device 1B includes a sample chamber 10, sample stand 11, a drive mechanism 12, an electron beam column 13, a focused ion beam column 14, a secondary charged particle detector 15, a transmission electron detector 16, an input unit 17, a display unit 18, and a control device 19B.

The control device 19B controls the overall operation of the charged particle beam device 1B. The control device 19B includes an electron beam control unit 20, a focused ion beam control unit 21, a drive control unit 22, a memory unit 23B, and a control unit 24B. In addition, as illustrated in FIG. 10, the control unit 24B includes a display control unit 30, an observation image generation unit 31, and a determination unit 32B.

Aside the processing conditions, a second trained model is stored in the memory unit 23B. The second trained model is a learning model that determines whether an input SEM image is an image of a specific layer or not. The second trained model is a machine-learning model trained using images (for example, SEM images) of each of a plurality of layers including a specific layer as training data. However, the invention is not limited thereto, and the second trained model may be a machine-learning model that is trained using the image of the specific layer to which the label is assigned and the images of layers other than the specific layer as training data.

The determination unit 32B inputs SEM images obtained in the exposure machining step to the second trained model and determines whether the specific layer is exposed based on a result of determination output from the second trained model and confidence level presenting certainty of the result of determination.

Hereinafter, an exposure machining method performed by the charged particle beam device 1B of the third embodiment will be described in detail. FIG. 11 is a flow diagram illustrating the exposure machining method performed by the charged particle beam device 1B of the third embodiment.

### [Exposure Machining Method]

The charged particle beam device 1B reads processing conditions stored in the memory unit 23B and starts FIB machining according to the processing conditions. First, the charged particle beam device 1B forms a new cross-section by performing slicing machining on the cross-section of the sample S by a predetermined amount by applying a focused ion beam (step S501: machining step). When the new cross-section is formed, the charged particle beam device 1B stops the FIB machining, irradiates the new cross-section formed with an electron beam, and generates an observation image (SEM image) of the cross-section (Step S502: image generation step). In other words, the observation image generation unit 31 executes an image generation step after the machining step.

The charged particle beam device 1B inputs the SEM image generated in the image generation step to the second trained model and obtains the determination result output from the second trained model (step S503). Then, the charged particle beam device 1B determines whether the determination result output from the second trained model is information indicating the specific layer (step S504: first determination step). When the determination result output from the second trained model is information indicating the specific layer, the charged particle beam device 1B determines whether the confidence level of the determination result is a predetermined threshold or more (step S505: second determination step). The charged particle beam device 1B determines that the specific layer is exposed when the confidence level of the determination result is the predetermined threshold or more (step S506). Then, when the determination result output from the second trained model is not information indicating the specific layer in step S504, the charged particle beam device 1B determines that the specific layer is not exposed and proceeds to step S501. In addition, when the confidence level of the determination result is less than the predetermined threshold in step S505, the charged particle beam device 1B determines that the specified layer is not exposed and proceeds to step S501. The processes from step S503 to step S506 are examples of the specific layer determination step.

After the exposure of the specific layer is detected, the charged particle beam device 1B may stop the FIB machining or resume the processing of the specific layer after switching to the processing conditions for the specific layer.

Thus, the charged-particle beam device 1B of the third embodiment has the same effects as the charged-particle beam device 1 of the first embodiment and improves the stability of the detection of the specific layer by using a confidence level threshold for the detection of the specific layer.

The charged particle beam device 1B of the third embodiment may execute the pre-processing described in the second embodiment.

### Fourth Embodiment

Hereinafter, a charged particle beam device 1C according to a fourth embodiment will be described in detail. In the description given below, parts that have the same functions as those in the first embodiment will be denoted by the same names and reference numerals, and a redundant description thereabout will be omitted. Compared to the charged particle beam device 1 of the first embodiment, the charged particle beam device 1C of the fourth embodiment differs in the process of determining whether a specific layer is exposed, but other functions and configurations are the same.

FIG. 12 is a diagram illustrating one example of the schematic configuration of the charged particle beam device 1C according to the fourth embodiment. As illustrated in FIG. 12, the charged particle beam device 1C includes a sample chamber 10, sample stand 11, a drive mechanism 12, an electron beam column 13, a focused ion beam column 14, a secondary charged particle detector 15, a transmission electron detector 16, an input unit 17, a display unit 18, and a control device 19C.

The control device 19C controls the overall operation of the charged particle beam device 1C. The control device 19C includes an electron beam control unit 20, a focused ion beam control unit 21, a drive control unit 22, a memory unit 23C, and a control unit 24C. In addition, as illustrated in FIG. 13, the control unit 24C includes a display control unit 30, an observation image generation unit 31, and a determination unit 32C.

Aside the processing conditions, a third trained model is stored in the memory unit 23C. The third trained model is a model that determines that determines an image of which layer among the plurality of layers an input image is. For example, the third trained model is a machine-learning model trained using labeled SEM images of each of the plurality of layers including a specific layer as training data.

In addition, information (hereinafter, referred to as “layer information”) on the order of lamination of each layer in the sample S is stored in the memory unit 23C. The lamination order is the order of the layers laminated in the lamination direction from the surface of the sample S. It is the order of the layers laminated in the lamination direction from the surface of the sample S. The FIB machining is slicing parallel or perpendicular to the layers laminated in the lamination direction. In other words, the lamination order is information on the processing order indicating which layer is processed first and which is processed second.

The determination unit 32C inputs SEM images obtained in the exposure machining step to the third trained model and identifies a layer (hereinafter, referred to as “machining layer”) being processed in the machining step based on the determination result output from the third trained model. Accordingly, the determination unit 32C can determine that a specific layer is exposed when the identified machining layer is the specific layer. During FIB machining, the determination unit 32C always checks whether FIB machining is performed on the layers according to the lamination order using the current machining layer and the layer information stored in the memory unit 23C. For example, since the machining layer is identified, the determination unit 32C can identify by how many layers the current machining layer is apart from the layer that is firstly processed. Therefore, the determination unit 32C may determine that a misidentification of the machining layer has occurred when the n-th machining layer currently being processed does not match the n-th layer stored as the layer information in the memory unit 23C.

For example, the determination unit 32C determines that the current machining layer is a second layer. The determination unit 32C assumes that as the FIB processing progresses, the machining layer changes based on the SEM image, and the new layer is determined to be the machining layer. In this case, the determination unit 32C reads the information of the layer stored in the memory unit 23 as the third layer and compares that layer with the machining layer. When the results of the comparison reveal that the layers do not match each other, the determination unit 32C determines that the machining layer is incorrectly identified.

Hereinafter, an exposure machining method performed by the charged particle beam device 1C of the fourth embodiment will be described in detail. FIG. 14 is a flow diagram illustrating the exposure machining method performed by the charged particle beam device 1C.

### [Exposure Machining Method]

The charged particle beam device 1C reads processing conditions stored in the memory unit 23C and starts FIB machining according to the processing conditions. First, the charged particle beam device 1C forms a new cross-section by performing slicing machining on the cross-section of the sample S by a predetermined amount by irradiating the sample S with a focused ion beam (step S601: machining step). When the new cross-section is formed, the charged particle beam device 1C stops the FIB machining, irradiates the new cross-section formed with an electron beam, and generates an observation image (SEM image) of the cross-section (Step S602: image generation step). In other words, the observation image generation unit 31 executes an image generation step after the machining step.

The charged particle beam device 1C inputs the SEM image generated in the image generation step to the third trained model and identifies a machining layer based on the determination result output from the third trained model (step S603). In addition, the charged particle beam device 1C also determines whether the identified machining layer is correct or not (step S604). For example, the charged particle beam device 1C identifies whether the identified machining layer is a layer conforming to the order of processing stored in the memory unit 23. When the identified machining layer is a layer conforming to the order of processing, the charged particle beam device 1C determines that the machining layer is correct. On the other hand, when it is determined that the machining layer is not a layer conforming to the order of processing, the charged particle beam device 1C identifies that the machining layer is correct and determines that misidentification of the machining layer has occurred. If the misidentification of the machining layer occurs, the FIB machining may be stopped.

When the identified machining layer is correct, the determination unit 32C determines whether the identified machining layer is a specific layer or not (step S605). When the identified machining layer is not the specific layer, the determination unit 32C determines that the specific layer is not exposed and returns to the process of step S601 to execute slicing machining again. On the other hand, the determination unit 32C determines that the specific layer is exposed when the identified machining layer is the specific layer. When the determination unit 32 determines that the specific layer is exposed, the charged particle beam device 1C finishes the series of processes shown in FIG. 14. That is, with the machining step, the image generation step, and the specific layer determination step being a set, the charged particle beam device 1C repeatedly executes the set of steps until exposure of the specific layer is detected in the specific layer determination step. In addition, the processes of step S603 to step S606 are examples of the specific layer determination step.

After the exposure of the specific layer is detected, the charged particle beam device 1C may stop the FIB machining or resume the processing of the specific layer after switching to the processing conditions for the specific layer.

Thus, the charged-particle beam device 1C of the fourth embodiment has the same effects as the charged-particle beam device 1 of the first embodiment and improves the stability of the detection of the specific layer by providing the process with regard to the misidentification of step S604 when detecting the specific layer.

In addition, the charged particle beam device 1C of the fourth embodiment may execute the pre-processing described in the second embodiment.

Here, as illustrated in FIG. 15, the charged particle beam device 1C may detect a layer switching point to a specific layer using the confidence level of the determination result output from the third trained model. Steps S611 through S613 in FIG. 15 are similar to steps S601 through S603, and thus a description thereof will be omitted. The charged particle beam device 1C determines whether or not the identified machining layer is a layer (k−1-th layer) positioned immediately ahead of the specific layer (k-th layer) (step S614). When it is determined that the identified machining layer is the layer (k−1-th layer) positioned immediately ahead of the specific layer (k-th layer), the charged particle beam device 1C determines whether or not the confidence level of the determination result output from the third trained model is decreased by a predetermined value or more (step S615). The charged particle beam device 1C detects a layer switch to the specific layer when the confidence level of the determination result is decreased by the predetermined threshold or more (step S616).

The confidence level is low when the specific layer begins to be exposed and peaks when the specific layer is fully exposed. In other words, the confidence level is decreased when the layer exposed by the FIB machining begins to switch to the specific layer. Therefore, when the confidence level falls after identifying the machining layer positioned immediately ahead of the specific layer, the charged particle beam device 1C of the fourth embodiment may determine that it is a switching point to the specific layer. In addition, the charged particle beam device 1C can also adjust the end point position of the FIB machining by continuing to excessively process the sample beyond the determined switching point to the specific layer. The step of detecting the switching point to the specific layer is included in the step of detecting the exposure of the specific layer.

For example, the charged particle beam device 1C temporarily stops the processing at the switching point to the specific layer and execute an additional control operation of continuing the FIB machining by a predetermined amount. For example, the charged particle beam device 1C may perform any of (a), (b), (c), and (d) described below as the additional control operation.

(a) Based on the number of frames of FIB machining until the layer switching position is detected, the FIB machining is stopped after the FIB machining corresponding to a specific number of frames is performed.

(b) Based on the number of slices of FIB machining until the layer switching position is detected, the FIB machining is stopped after the FIB machining corresponding to a specific number of frames is performed.

(c) Based on the contrast value of the SEM image at the time of detecting the layer switching position, the processing is stopped after a specified contrast value is changed.

(d) After detecting the layer switching position, the processing is stopped after the contrast value of the SEM image reaches the specified value.

### Fifth Embodiment

Hereinafter, a charged particle beam device 1D according to a fifth embodiment will be described in detail. In the description given below, parts that have the same functions as those in the first embodiment will be denoted by the same names and reference numerals, and a redundant description thereabout will be omitted. Compared to the charged particle beam device 1 of the first embodiment, the charged particle beam device 1D of the fifth embodiment differs in that a predetermined amount for the machining step can be adjusted. However, other functions and configurations are the same.

FIG. 16 is a diagram illustrating one example of the schematic configuration of the charged particle beam device 1D according to the fifth embodiment. As illustrated in FIG. 16, the charged particle beam device 1D includes a sample chamber 10, sample stand 11, a drive mechanism 12, an electron beam column 13, a focused ion beam column 14, a secondary charged particle detector 15, a transmission electron detector 16, an input unit 17, a display unit 18, and a control device 19D.

The control device 19D controls the overall operation of the charged particle beam device 1D. The control device 19D includes an electron beam control unit 20, a focused ion beam control unit 21, a drive control unit 22, a memory unit 23D, and a control unit 24D. In addition, as illustrated in FIG. 17, the control unit 24D includes a display control unit 30, an observation image generation unit 31, a determination unit 32D, and a predetermined amount adjusting unit 34.

Aside the processing conditions, a third trained model is stored in the memory unit 23D. In addition, layer information is stored in the memory unit 23D.

Like the fourth embodiment, the determination unit 32D inputs SEM images obtained in the exposure machining step to the third trained model and identifies a machining layer being processed in the machining step based on the determination result output from the third trained model. Accordingly, the determination unit 32D can determine that a specific layer is exposed when the identified machining layer is the specific layer.

The predetermined amount adjusting unit 34 decreases the predetermined amount as the machining layer becomes closer to the specific layer. For example, the predetermined amount adjusting unit 34 sets the predetermined amount to a first predetermined amount. When the machining layer is a layer positioned immediately ahead of the specific layer, the predetermined amount adjusting unit 34 sets the predetermined amount to a second predetermined amount that is smaller than the first predetermined amount.

Hereinafter, an exposure machining method performed by the charged particle beam device 1D of the fifth embodiment will be described in detail. FIG. 18 is a flow diagram illustrating the exposure machining method performed by the charged particle beam device 1D of the fifth embodiment.

### [Exposure Machining Method]

The charged particle beam device 1D reads processing conditions stored in the memory unit 23D and starts FIB machining according to the processing conditions. First, the charged particle beam device 1D sets a predetermined amount to a first predetermined amount (step S701). Next, the charged particle beam device 1D forms a new cross-section by performing slicing machining on the cross-section of the sample S by the predetermined amount by applying a focused ion beam (step S702: machining step). When the new cross-section is formed, the charged particle beam device 1D stops the FIB machining, irradiates the new cross-section formed with an electron beam, and generates an observation image (SEM image) of the cross-section (Step S703: image generation step). In other words, the observation image generation unit 31 executes an image generation step after the machining step.

The charged particle beam device 1D inputs the SEM image generated in the image generation step to the third trained model and identifies a machining layer based on the determination result output from the third trained model (step S704). In addition, the charged particle beam device 1D identifies whether the identified machining layer is the specific layer (step S705). Here, the specific layer is the k-th layer from the surface of the sample in a direction in which layers are stacked. When the identified machining layer is not the specific layer, the charged particle beam device 1D determines whether the identified machining layer is a (k−n)-th layer (n is an integer) (step S706). For example, n is not particularly limited if the integer satisfies n<k, and n is preferably “1” in terms of faster exposure machining. When the identified machining layer is the (k−n)-th layer, the charged particle beam device 1D changes the predetermined amount for the machining step from the first predetermined amount to the second predetermined amount (step S707). When the predetermined amount is changed, the process proceeds to step S702. When the identified machining layer is not the (k−n)-th layer, the charged particle beam device 1D does not change the predetermined amount, and the processing flow proceeds to step S702.

When the identified machining layer is identified to be the specific layer in step S705, the charged particle beam device 1D determines that the specific layer is exposed (step S708). After the exposure of the specific layer is detected, the charged particle beam device 1D may stop the FIB machining or resume the processing of the specific layer after switching to the processing conditions for the specific layer. In addition, the processes of step S704 to step S708 are examples of the specific layer determination step.

In this way, the charged-particle beam device 1D of the fifth embodiment has the same effects as the charged-particle beam device 1 of the first embodiment and improves the accuracy of a layer detection position by reducing the predetermined amount for the FIB machining at a position close to the specific layer.

In addition, the charged particle beam device 1D of the fifth embodiment may execute the pre-processing described in the second embodiment.

### Sixth Embodiment

Hereinafter, a charged particle beam device 1E according to a sixth embodiment will be described in detail. In the description given below, parts that have the same functions as those in the first embodiment will be denoted by the same names and reference numerals, and a redundant description thereabout will be omitted. Compared to the charged particle beam device 1 of the first embodiment, the charged particle beam device 1E of the sixth embodiment differs in that a predetermined amount for the machining step can be adjusted. However, other functions and configurations are the same.

FIG. 19 is a diagram illustrating one example of the schematic configuration of the charged particle beam device 1E according to the sixth embodiment. As illustrated in FIG. 16, the charged particle beam device 1E includes a sample chamber 10, sample stand 11, a drive mechanism 12, an electron beam column 13, a focused ion beam column 14, a secondary charged particle detector 15, a transmission electron detector 16, an input unit 17, a display unit 18, and a control device 19E.

The control device 19E controls the overall operation of the charged particle beam device 1E. The control device 19E includes an electron beam control unit 20, a focused ion beam control unit 21, a drive control unit 22, a memory unit 23E, and a control unit 24E. In addition, as illustrated in FIG. 20, the control unit 24E includes a display control unit 30, an observation image generation unit 31, a determination unit 32E, and a switching unit 40.

Aside the processing conditions, the third trained model is stored in the memory unit 23E. In addition, layer information is stored in the memory unit 23E.

Like the fourth embodiment, the determination unit 32E inputs SEM images obtained in the exposure machining step to the third trained model and identifies a machining layer being processed in the machining step based on the determination result output from the third trained model. Accordingly, the determination unit 32E can determine that a specific layer is exposed when the identified machining layer is the specific layer.

The switching unit 40 switches between a first mode and a second mode. The first mode is a mode in which FIB machining and SEM image generation are concurrently performed. The second mode is a mode in which FBI machining and SEM image generation are performed at different points in time. For example, the switching unit 40 executes the first mode and then switches to the second mode from the first mode when the machining layer is a layer positioned immediately ahead of the specific layer.

Hereinafter, an exposure machining method performed by the charged particle beam device 1E of the sixth embodiment will be described in detail. FIG. 21 is a flow diagram illustrating the exposure machining method performed by the charged particle beam device 1E of the sixth embodiment.

### [Exposure Machining Method]

The charged particle beam device 1E reads machining conditions stored in the memory unit 23E and starts FIB machining according to the processing conditions. First, the charged particle beam device 1E sets an operation mode to the first mode (step S801). Thus, since the operation mode is the first mode, the charged particle beam device 1E irradiates a sample S with a focused ion beam so that a cross-section of the sample S is sliced by the predetermined amount, and SEM images are generated (step S802).

The charged particle beam device 1E inputs the SEM image generated in the image generation step to the third trained model and identifies a machining layer based on the determination result output from the third trained model (step S803). In addition, the charged particle beam device 1E identifies whether the identified machining layer is a (k−n)-th layer (step S804). When the identified machining layer is the (k−n)-th layer, the charged particle beam device 1E changes the operation mode from the first mode to the second mode (step S805). When the identified machining layer is not the (k−n)-th layer, the charged particle beam device 1E proceeds to step S802.

When the operation is switched to the second mode, the charged particle beam device 1E forms a new cross-section by performing slicing machining on the cross-section of the sample S by the predetermined amount by applying a focused ion beam (step S806). When the new cross-section is formed, the charged particle beam device 1E stops the FIB machining, irradiates the new cross-section formed with an electron beam, and generates an SEM image of the cross-section (Step S807). The charged particle beam device 1E inputs the SEM image generated in the step s807 to the third trained model and identifies a machining layer based on the determination result output from the third trained model (step S808). In addition, the charged particle beam device 1E identifies whether the identified machining layer is the specific layer (step S809). When the identified machining layer is identified to be the specific layer, the charged particle beam device 1E determines that the specific layer is exposed (step S810). On the other hand, when the identified machining layer is not the specific layer, the charged particle beam device 1E proceeds to step S806. In addition, the processes of step S803 to step S810 are examples of the specific layer determination step.

In this way, the charged-particle beam device 1E of the sixth embodiment has the same effects as the charged-particle beam device 1 of the first embodiment and can achieve fast processing and highly accurate detection of a specific layer by executing FIB machining and SEM image generation at different points in time at a position close to the specific layer.

In addition, the charged particle beam device 1E of the sixth embodiment may execute the pre-processing described in the second embodiment.

The embodiments of the invention have been described in detail with reference to the drawings, but the specific configuration is not limited to the embodiments and can include designs that do not depart from the gist of the invention.

Throughout the specification, when a portion is referred as “including”, “having”, or “being provided with” a component, other components are not excluded but may be included, unless otherwise stated.

In addition, the term “ . . . unit” in the specification means a unit that processes at least one function or operation, the unit may be embodied as hardware or software, or a combination of hardware and software.

In addition, all or part of the above-mentioned control devices 19, 19A, 19B, 19C, 19D, 19E may be implemented by a computer. In this case, the computer may be equipped with a processor such as CPU and GPU, and a computer-readable recording medium. Therefore, a program to implement all or part of the functions of the control devices in a computer may be recorded on the computer-readable recording medium, and the program recorded on the recording medium may be read by the processor and executed. Here, the term “computer-readable recording media” refers to portable media such as flexible disks, optical magnetic disks, ROMS, CD-ROMs, and other storage devices such as hard disks built into computer systems. In addition, the “computer-readable recording media” may also include something that dynamically holds the program for a short period of time, such as a communication line in the case of transmitting the program via a network such as the Internet or a communication line such as a telephone line, and devices that hold the program for a certain period of time, such as a volatile memory provided in a computer system serving as a server or a client. The program may be used to implement some of the aforementioned functions, and furthermore, the aforementioned functions may be implemented in conjunction with a program recorded in the computer system and may be implemented using a programmable logic device such as an FPGA.

### EXPLANATION OF REFERENCE NUMERALS

1, 1A, 1B, 1C, 1D, 1E: Charged particle beam device
13: Ion beam column
14: Focused ion beam column
15: Secondary charged particle detector
16: Transmission electron detector
19, 19A, 19B, 19C, 19D, 19E: Control device
20: Electron beam control unit
21: Focused ion beam control unit
22: Drive control unit
23, 23B, 23C, 23D, 23E: Memory unit
24, 24A, 24B, 24C, 24D, 24E: Control unit
31: Observation image generation unit
32, 32B, 32C, 32D, 32E: Determination unit
33: Pre-processing unit
34: Predetermined amount adjustment unit
40: Switching unit

1. A machining method comprising:
a machining step of processing a cross-section of a sample in which a plurality of layers is laminated by a predetermined amount by irradiating the sample with a focused ion beam;
an image generation step of generating first observation image, which is an observation image of cross-section of the sample, by irradiating the sample with an electron beam at a point in time different from processing of the cross-section after the machining step is finished;
a specific layer determination step of determining whether a specific layer among the plurality of layers has been exposed based on the first observation image; and
a pre-processing step, which is a step being executed before the machining step that is executed first among a plurality of the machining steps that are repeatedly executed, of focusing the electron beam based on a second observation image, which is an observation image of a pattern of deposits on a surface of the sample and in a different magnifying power from a magnifying power of the first observation image,
wherein, in the machining step, contrast of the observation image is obtained while executing processing of the cross-section by irradiating the sample with the focused ion beam and, in case the contrast changes, stopping processing of the cross-section and focusing the electron beam.

2. A machining method comprising:
a machining step of processing a cross-section of a sample in which a plurality of layers is laminated by a predetermined amount by irradiating the sample with a focused ion beam;
an image generation step of generating an observation image of cross-section of the sample by irradiating the sample with an electron beam after the machining step is finished; and
a specific layer determination step of determining whether a specific layer among the plurality of layers is exposed based on the observation image,
wherein, with the machining step, the image generation step, and the specific layer determination step being a set, the set is repeatedly executed until exposure of the specific layer is detected in the specific layer determination step.

3. (canceled)

4. The machining method according to claim 2, further comprising a pre-processing step of focusing the electron beam, the pre-processing step being executed before the machining step that is executed initially,
wherein the pre-processing step comprises:
an observation image acquisition step of acquiring the observation image while processing the cross-section by irradiating the sample with the focused ion beam;
an exposure determination step of determining whether a layer having a pattern is exposed or not by inputting the observation image acquired in the observation image acquisition step to a learning model that has been previously trained with observation images of layers having no pattern and observation images of the layers having the pattern among the plurality of layers as training data; and
a focusing step of stopping the processing of the cross-section and focusing the electron beam in case it is determined that a layer having the pattern is exposed in the exposure determination step.

5. The machining method according to claim 2, further comprising a pre-processing step of focusing the electron beam based on the observation image of a pattern of deposits on a surface of the sample,
wherein the pre-processing step is executed before the machining step that is executed initially.

6. The machining method according to claim 2, wherein the specific layer determination step determines whether the specific layer is exposed, based on a result of determination output from a learning model that determines whether an image that is input is an image of the specific layer, by inputting the observation image generated in the image generation step to the learning model, and confidence level presenting certainty of the result of the determination.

7. The machining method according to claim 2, wherein the specific layer determination step identifies a machining layer, which is a layer being processed in the machining step, based on a result of determination output from a learning model that determines an image of which layer among the plurality of layers an input image is, by inputting the observation image generated in the image generation step to the learning model, and determines that the machining layer is mis-identified in case the machining layer identified is different from a preset layer is mis-identified in case the machining layer identified is different from a preset layer.

8. The machining method according to claim 2, wherein the specific layer determination step identifies a machining layer, which is a layer being processed in the machining step, based on a result of determination output from a learning model that determines an image of which layer among the plurality of layers an input image is, by inputting the observation image obtained in the image generation step to the learning model, and detects layer switching to the specific layer in case the machining layer is a layer that is immediately before the specific layer and confidence level of the result of determination is decreased.

9. The machining method according to claim 2, wherein the specific layer is a k-th layer from a surface of the sample in a direction in which layers are stacked:
the specific layer determination step identifies a machining layer, which is a layer being processed in the machining step, based on a result of determination output from a learning model that determines an image of which layer among the plurality of layers an input image is, by inputting an observation image generated in the image generation step to the learning model and
the machining step reduces the predetermined amount in case the machining layer determined in the specified layer determination step is a (k−n)-th layer (n is an integer).

10. A machining method comprising:
a machining step of processing a cross-section of a sample in which a plurality of layers is laminated by a predetermined amount by irradiating the sample with a focused ion beam;
an image generation step of generating first observation image of a cross-section of the sample by irradiating the sample with an electron beam;
a specific layer determination step of determining whether a specific layer among the plurality of layers is exposed, based on the observation image; and
a pre-processing step, which is a step being executed before the machining step that is executed first among a plurality of the machining steps that are repeatedly executed, of focusing the electron beam based on a second observation image, which is an observation image of a pattern of deposits on a surface of the sample and in a different magnifying power from a magnifying power of the first observation image,
wherein the specific layer is a k-th layer from a surface of the sample in a direction in which layers are stacked,
the specific layer determination step identifies a machining layer, which is a layer being processed in the machining step, based on a result of determination output from a learning model that determines an image of which layer among the plurality of layers an input image is, by inputting the observation image generated in the image generation step to the learning model; and
the machining step and the image generation step are executed concurrently when the processing of the sample starts and in case the machining layer is a (k−n)-th layer (n is an integer), the machining step and the image generation step are executed at different points in time.

11. A charged particle beam device comprising:
a focused ion beam column configured to process a cross-section of a sample in which a plurality of layers is laminated by a predetermined amount by irradiating the sample with a focused ion beam;
an electron beam column configured to irradiate the sample with an electron beam after the predetermined amount of processing with the focused ion beam column is finished at a point in time different from processing of the cross-section;
an observation image generation unit configured to generate first observation image, which is an observation image of a cross-section of the sample based on electrons generated from the sample; and
a determination unit configured to determine whether a specific layer among the plurality of layers is exposed based on the first observation image,
wherein the electron beam column, before the machining step that is executed first among a plurality of the machining steps that are repeatedly executed, focuses the electron beam based on a second observation image, which is an observation image of a pattern of deposits on a surface of the sample and in a different magnifying power from a magnifying power of the first observation image.

12. The machining method according to claim 1, wherein, with the machining step, the image generation step, and the specific layer determination step being a set, the set is repeatedly executed until exposure of the specific layer is detected in the specific layer determination step.

13. The machining method according to claim 1, wherein the second observation image is in a magnifying power lower than a magnifying power in which the first observation image is.
